(19) United States
(12) Patent Application Publication
(10) Pub. No.: US 2010/0329157 A1
(43) Pub. Date: Dec. 30, 2010

(54) Even-Order Harmonics Calibration

(75) Inventors: Nianwei Xing, San Jose, CA (US); David H. Shen, Campbell, CA (US); Axel Schuur, Mountain View, CA (US); Ann P. Shen, Saratoga, CA (US)

Correspondence Address: ANN SHEN, 21037 Dorsey Way, Saratoga, CA, 95070, US

(73) Assignee: NANOAMP SOLUTIONS INC. (CAYMAN), Santa Clara, CA (US)

(21) Appl. No.: 12/495,064

(22) Filed: Jun. 30, 2009

Related U.S. Application Data
(60) Provisional application No. 61/220,383, filed on Jun. 25, 2009.

(51) Int. Cl. H04B 7/005; H03F 3/45; G06G 7/12

(52) U.S. Cl. 370/278; 330/253; 327/355

(57) ABSTRACT

Circuits and methods for a differential circuit involve having one of more pairs of differential transistors with back-gate terminals, where each of the back-gate terminals is biased by a tunable back-gate voltage to compensate for circuit mismatches in the differential circuit and reduce or eliminate even-order harmonics in the output signal. A compensation circuit can be configured to receive data relating to the differential output signal of the differential circuit, and to supply one or more back-gate voltages to the back-gate terminals of the differential transistors to adjust threshold voltages of the differential transistors and suppress even-order harmonics in the differential output signal of the differential circuit.

### CROSS-REFERENCE TO RELATED APPLICATIONS

This application claims the benefit of priority to U.S. Provisional Application No. 61/220,383, entitled “EVEN-ORDER HARMONICS CALIBRATION,” filed on Jun. 25, 2009, the disclosure of which is incorporated by reference.

### TECHNICAL FIELD

This disclosure relates to mismatch calibration for differential circuits, for example, in radio frequency (RF) or audio frequency applications.

### BACKGROUND

Metal-oxide-semiconductor field-effect transistor (MOSFET) devices have four terminals, in which one terminal can be coupled to a bulk region. The potential of the bulk region can vary from the potentials of the source, drain, and gate terminals of the MOSFET. At least two MOSFET devices can be configured in a circuit design with differential inputs and/or outputs.

### SUMMARY

Aspects of the disclosed techniques and designs involve a circuit that includes a first transistor having a first back-gate terminal, a second transistor having a second back-gate terminal, an input terminal coupled to the first and second transistors and configured to receive an input signal, and an output terminal coupled to the first and second transistors and configured to provide a differential output signal. The circuit includes a compensation circuit configured to supply one or more back-gate voltages to the first back-gate terminal or the second back-gate terminal such that a circuit mismatch is compensated.

These and other implementations can optionally include one or more of the following features. The input signal can be a differential signal or a single-ended signal. The compensation circuit can be configured to supply a first back-gate voltage to the first back-gate terminal and a second back-gate voltage to the second back-gate terminal such that the circuit mismatch of the circuit is compensated. The first and second transistors may be a differential pair of transistors, and the circuit can be a differential circuit. The circuit can include a third transistor having a third back-gate terminal, a fourth transistor having a fourth back-gate terminal. The third transistor can be coupled to the first transistor, and the fourth transistor can be coupled to the second transistor. The compensation circuit can be configured to supply one or more back-gate voltages to the third back-gate terminal or the fourth back-gate terminal such that the circuit mismatch is compensated. The output terminal can be coupled to the third and the fourth transistors. The compensation circuit can be further configured to supply the third back-gate voltage to the third back-gate terminal and the fourth back-gate voltage to the fourth back-gate terminal such that a circuit mismatch is compensated. The second back-gate voltage can be equal to the first back-gate voltage and the third back-gate voltage can be equal to the fourth back-gate voltage. The third back-gate voltage can be equal to the first back-gate voltage and the fourth back-gate voltage can be equal to the second back-gate voltage. The circuit can include one or more pairs of differential transistors coupled to the first and second transistors, and the third and fourth transistors, in which the back-gate terminals of the one or more pairs of differential transistors are coupled to the one or more back-gate voltages. At least one of the back-gate voltages can be different from any supply voltages of the circuit. The compensation circuit can be configured to vary the one or more back-gate voltages provided to the first back-gate terminal or the second back-gate terminal such that even-order harmonics in the output signal are reduced or eliminated. The compensation circuit can include an input terminal configured to receive a control input signal. The control input signal can be a function of the differential output signal. The compensation circuit can include a digital signal processor. The compensation circuit can include an analog-to-digital converter (ADC). The compensation circuit can be configured to utilize a control input signal from a baseband circuit or a digital signal processor that is configured to compare a direct current level in the differential output signal with a fixed value or a variable value. The compensation circuit can include one or more back-gate bias voltage generating circuits. The compensation circuit can include a decoder for controlling the one or more back-gate bias voltage generating circuits. The compensation circuit can be configured to compare a direct current level in the differential output signal with a fixed or a varying value. At least one of the back-gate bias voltage generating circuits can include a digital-to-analog converter (DAC). The digital-to-analog converter can include a sigma-delta DAC, or a type of over-sampling or noise-shaping DAC. The compensation circuit can include an impedance network. The compensation circuit can include an analog voltage ramping circuit or a sweeping circuit.

In some aspects, some techniques includes features for a method of compensating for circuit mismatches in a differential circuit. The method involves biasing a back-gate terminal of a first transistor in a pair of transistors with a first back-gate voltage, biasing a back-gate terminal of a second transistor in the pair of transistors with a second back-gate voltage, and tuning the first or the second back-gate voltages to compensate for circuit mismatches in the differential circuit.

These and other implementations can optionally include one or more of the following features. The tuning of the first or second back-gate voltages can involve tuning the first or second back-gate voltages to compensate for the circuit mismatch in order to suppress even-order harmonics in a differential output signal. The tuning of the first or second back-gate voltages can involve comparing a direct current level in a differential output signal with a fixed or a varying value. The tuning of the first or the second back-gate voltages can involve increasing or decreasing the first or the second back-gate voltages from respective source voltages of the first or second transistors or from a power supply. The tuning of the first or the second back-gate voltages can involve tuning the first or the second back-gate voltages using a compensation circuit. The method can also include forming an input control signal for the compensation circuit using a differential output signal of the differential circuit. Forming the input control signal can involve generating the input control signal using a digital signal from a baseband processor or a digital signal processor. The compensation circuit can include back-gate bias voltage generating circuits, in which the back-gate bias voltage generating circuits can include digital-to-analog converters (DAC), impedance networks, or analog voltage ramping circuits. The method can involve decoding the input control signal in the compensation circuit. The method can involve utilizing an analog-to-digital converter or a digital signal processor in the compensation circuit to determine the back-gate voltages.

In some aspects, some techniques includes features for a circuit. The circuit includes a differential operational amplifier that includes: a first transistor having a first back-gate terminal; a second transistor having a second back-gate terminal; an input terminal coupled to the first and second transistors and configured to receive an input signal; and an output terminal coupled to the first and second transistors and configured to provide a differential output signal. The circuit also includes a compensation circuit configured to receive data relating to the differential output signal of the differential operational amplifier and to supply one or more back-gate voltages to the first back-gate terminal or the second back-gate terminal to adjust a threshold voltage of each of the first and second transistors and suppress even-order harmonics in the differential output signal.

These and other implementations can optionally include one or more of the following features. The compensation circuit can include back-gate bias voltage generating circuits, an analog-to-digital converter, a digital signal processor, or a decoder for controlling the back-gate bias voltage generating circuits. The back-gate bias voltage generating circuits can include a resistive network, an impedance network, a digital-to-analog converter (DAC), an analog voltage ramping circuit, or a sweeping circuit. An input control signal can be coupled to the compensation circuit, in which the input control signal can be determined by comparing a direct current level in the differential output signal to a fixed or a variable value. The circuit can include a processor to generate the input control signal based on the differential output signal. The compensation circuit can be configured to generate the one or more back-gate voltages from a source voltage of the first or second transistors or from a power supply. The first transistor and the second transistor can include a first pair of differential transistors.

In some aspects, some techniques includes features for a circuit. The circuit includes a differential mixer circuit that includes a first transistor having a first back-gate terminal, a second transistor having a second back-gate terminal, a first input terminal coupled to the first and second transistors at a stage in the differential mixer circuit and configured to receive a first input signal, and a second input terminal coupled to the first and second transistors at the same stage in the differential mixer and configured to receive a second input signal. The differential mixer circuit is configured to mix the first and second input signals to generate a differential output signal. The circuit includes a compensation circuit configured to receive data relating to the differential output signal of the differential mixer circuit and to supply one or more back-gate voltages to the first back-gate terminal or the second back-gate terminal to adjust a threshold voltage of each of the first and second transistors and suppress even-order harmonics in the differential output signal.

These and other implementations can optionally include one or more of the following features. The stage of the differential mixer circuit can include a first stage of the differential mixer circuit. The stage of the differential mixer circuit can be a stage that is after the first stage of the differential mixer circuit. The differential mixer circuit can be a passive differential mixer circuit. The differential mixer can be an active differential mixer circuit. The differential mixer circuit can include a second stage. The second stage can include a third transistor having a third back-gate terminal, and a fourth transistor having a fourth back-gate terminal. The third and fourth transistors can couple to the first and second transistors, and the third and fourth back-gate terminals can be configured to receive the one or more back-gate voltages. The second stage can include a third input terminal coupled to the third and fourth transistors and configured to receive a third input signal to mix with the differential output signal of the first stage of the differential mixer circuit to generate a second differential output signal and to suppress even-order harmonics in the second differential output signal. The first input signal can include a radio or audio frequency signal. The second input signal can include a first local oscillator signal, and the third input signal can include a second local oscillator signal. Phases of the first and the second local oscillator signals can be different, frequencies of the first and the second local oscillator signals can be different, and/or duty cycles of the first and the second local oscillator signals can be different. The first input signal can be a radio or audio frequency signal, and the second input signal can be a local oscillator signal.

In some aspects, some techniques include features for a system. The system includes an antenna to receive an input radio frequency (RF) signal, and a duplexer to isolate the input radio frequency signal and an output radio frequency signal. The duplexer is configured to receive the input radio frequency signal from the antenna, receive an output radio frequency signal from a transceiver via a power amplifier, and transmit the input radio frequency signal to the transceiver. The transceiver includes at least one low noise amplifier to amply the input radio frequency signal and generate an amplified RF signal, a compensation circuit, and a synthesizer that includes at least one differential oscillator to utilize the amplified RF signal and generate at least a first differential oscillator signal and at least a second differential oscillator signal. At least one of the differential oscillators includes a first transistor having a first back-gate terminal, a second transistor having a second back-gate terminal, an input terminal coupled to the first and second transistors and configured to receive an input signal, and an output terminal coupled to the first and second transistors and configured to provide a differential output signal for the differential oscillator. The compensation circuit is configured to receive data relating to the differential output signal of the differential oscillator and to supply one or more back-gate voltages to the first back-gate terminal or the second back-gate terminal to adjust a threshold voltage of each of the first and second transistors and suppress even-order harmonics in the differential output signal of the differential oscillator.

These and other implementations can optionally include one or more of the following features. The system can include any combination of one or more components for receivers, transmitters, and transceivers. Control circuits can include a digital circuit or a microprocessor.

The details of one or more implementations are set forth in the accompanying drawings and the description below. Other features will be apparent from the description and drawings, and from the claims.

### DESCRIPTION OF THE DRAWINGS

FIG. 1 depicts a schematic of an example of a differential circuit that tunes back-gate voltages for compensating circuit mismatches, which may reduce or eliminate even order harmonics.

FIG. 2 depicts a schematic of an example of a differential circuit having two pairs of transistors that tune back-gate voltages for compensating circuit mismatches, which may reduce or eliminate even order harmonics.

FIG. 3 depicts a schematic of an example of an operational amplifier that tunes back-gate voltages for compensating circuit mismatches, which may reduce or eliminate even order harmonics.

FIG. 4 depicts a schematic of an example of an operational amplifier with sigma-delta DACs for back-gate voltage generation.

FIG. 5 depicts a schematic of an example of a passive mixer circuit that tunes back-gate voltages for compensating circuit mismatches, which may reduce or eliminate even order harmonics.

FIG. 6 depicts a schematic of an example of a two-stage passive mixer circuit that tunes back-gate voltages for compensating circuit mismatches, which may reduce or eliminate even order harmonics.

FIG. 7 depicts a flow chart of an example of an algorithm for controlling back-gate voltage generations.

FIG. 8 depicts a schematic of an example of a direct conversion transceiver that tunes back-gate voltages for compensating circuit mismatches, which may reduce or eliminate even order harmonics.

### DETAILED DESCRIPTION

This disclosure relates to mismatch calibration for differential circuits, for example, in radio frequency (RF) or audio frequency applications. Some embodiments for circuits and methods for a differential circuit involve having one of more pairs of transistors with back-gate terminals, where each of the back-gate terminals is biased by a tunable back-gate voltage to compensate for differential circuit mismatches and reduce or eliminate even-order harmonics in the output signal of the differential circuit.

For a linear system, the output signal can be expressed as a linear combination of the individual input signals. The linearity requirements of a system or a component can depend on its application(s). For a nonlinear system, the output signal can be expressed as a polynomial function of input signals, e.g.,

y(t)=a₁*x(t)+a₂*x(t)²+a₃*x(t)³+a₄*x(t)⁴+ (1)

where y(t) represents a time variant output, x(t) represents a time variant input, and the aᵢ's represent time-variant transfer coefficients. For small signal approximations, high-order terms may be negligible, and the time-variant transfer coefficient a₁ may be considered as a small-signal gain of the system. Higher order terms may be taken into account for some applications to ensure that circuits in those systems can meet system linearity requirements. In some implementations, a differential signal can be represented as two equal signals with opposite signs:

x(t): x₋(t)=−x₊(t) and y(t): y₋(t)=−y₊(t), (2)

where x₊(t), x₋(t), y₊(t), and y₋(t) represent time variant signals. The differential output [y₊(t), y₋(t)] can be expressed as a function of the differential input [x₊(t), x₋(t)], e.g.,

y₊(t)=a₁*x₊(t)+a₂*x₊(t)²+a₃*x₊(t)³+a₄*x₊(t)⁴+ (3)

y₋(t)=a₁*x₋(t)+a₂*x₋(t)²+a₃*x₋(t)³+a₄*x₋(t)⁴+ (4)

By substituting the expression (2) above, x₋(t)=−x₊(t) and y₋(t)=−y₊(t), into expressions (3) and (4), the following expression can be obtained.

a₂*x₊(t)²+a₄*x₊(t)⁴+ . . . =0 and a₂*x₋(t)⁴+ . . . =0 (5)

Accordingly, all of the even transfer coefficients aᵢ can be zero, where indices i are even numbers (e.g., i=2, 4, 6, 8, . . . ). As a result, the output signal of an ideal fully-symmetric differential circuit may not have even order terms.

For a sinusoid input signal x(t)=A*cos(wt), where w is the input frequency, the output signal y(t) can be expressed as:

y(t)=[a₂*A²/2+3*a₄*A⁴/8+ . . . ]+[a₁*A+3*a₃*A³/4+ . . . ]*cos(wt)+[a₂*A²/2+a₄*A⁴/2+ . . . ]*cos(2wt)+[a₃*A³/4+ . . . ]*cos(3wt)+[a₄*A⁴/8+ . . . ]*cos(4wt)+ . . . (6)

where the term with the input frequency w is called the fundamental and the higher order terms are called the harmonics. From expression (6), even-order harmonics can result from even aᵢ's when each index i is an even number, and odd-order harmonics can result from odd aᵢ's when each index i is an odd number. Even-order harmonics may not exist in an ideal differential circuit, with aᵢ's for each i being an even number. However, in a real-world, non-ideal implementation, circuit mismatches can be present, which can degrade the symmetry of the differential circuit, and can generate finite even-order harmonics.

The dominate even-order harmonics in the output signal y(t) can be the zeroth-order term, e.g., the direct current (DC) level expressed as [a₂*A²/2+3*a₄*A⁴/8+ . . . ] in expression (6). For small signal approximations, the higher-order terms (e.g., the latter terms after a few initial terms) usually can be negligibly small. The higher-order harmonics may have much higher frequencies than the fundamental term, and usually can be easily attenuated by the differential circuit to not greatly affect circuit performance or functionality.

An additional amount of asymmetry can be provided to compensate for the mismatches of the differential circuit. For example, some implementations can compensate for mismatches in differential circuits by tuning a bulk bias (body effect), also referred as the back-gate bias of MOSFET transistors in a circuit, e.g., a differential circuit. A transistor's device characteristics can be modified by adjusting the back-gate or bulk potential relative to the potential of other transistor terminals or relative to a supply voltage. For example, in the case of an N-channel metal-oxide-semiconductor (NMOS) transistor, the threshold voltage, e.g., the minimum gate-source voltage for the transistor to turn on, can increase as the potential of the back-gate or bulk becomes increasingly negative to that of the source terminal. The threshold voltage of an NMOS transistor can also decrease as the potential of the back-gate or bulk becomes increasingly positive to that of the source terminal. The threshold voltage Vₜ of a MOSFET transistor can be expressed as:

Vₜ=Vₜₒ+γ*[(2*φ_{F}−V_{BS})^{1/2}−(2*φ_{F})^{1/2}], (7)

where Vₜₒ represents the threshold voltage at zero bulk-to-source voltage, φ_{F} represents the Fermi level in the deep bulk, V_{BS} represents the bulk-to-source voltage, and γ represents the MOSFET body effect parameter and can be a positive number typically smaller than 1 for MOSFET transistors.

For a P-channel metal-oxide-semiconductor (PMOS) transistor, as the back-gate potential of the PMOS transistor becomes increasingly negative relative to the potential of the source terminal, the threshold potential can increase. The threshold potential can also decrease as the back-gate potential PMOS transistor becomes increasingly positive relative to the potential of the source terminal.

In a small signal model, for example, a differential circuit can be approximated by adding a dependent circuit source that is controlled by the back-gate voltage. This can be referred to as the back-gate transconductance. The back-gate transconductance can be a derivative of drain current with respect to bulk-to-source voltage, e.g., g_{mb}=i_{d}/V_{BS}, where g_{mb} represents the back-gate transconductance, and i_{d} represents the drain current. Accordingly, changing the threshold voltages of transistors in a differential circuit can tune its outputs to compensate for mismatches, thereby reducing or eliminating even-order harmonics in the output signals.

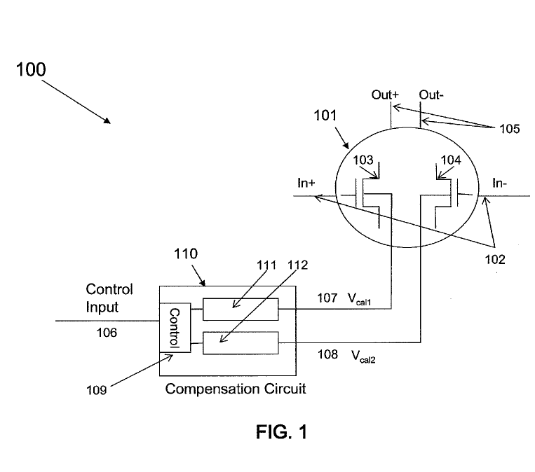

FIG. 1 depicts a schematic of an example of a circuit 100, in which the circuit 100 includes a differential circuit 101 with a minimum of one pair of transistors 103 and 104, and a compensation circuit 110 for adjusting the back-gate voltages of the transistors 103 and 104. The transistors 103, 104 can be identical (or nearly identical). The compensation circuit 110 includes a control circuit 109, a compensation control input 106, and back-gate bias voltage generating circuits 111 and 112 to generate analog output back-gate voltages V_{cal1}, V_{cal2} at terminals 107, 108. The control circuit 109 can control the back-gate bias voltage generating circuits 111 and 112 to generate back-gate voltages V_{cal1}, V_{cal2}, respectively. In some implementations, the back-gate bias voltage generating circuits 111 and 112 are identical in design (e.g., size, layout, implementation, configuration, etc.), and in other implementations those circuits 111, 112 are different in design.

Even-order harmonics maybe present in a differential output signal Out₊−Out− at a differential output terminal 105 of circuit 100. The compensation circuit 110 can be configured to perform even-order harmonic calibration with respect to the output signal of the differential circuit 101. For example, instead of having the back-gate terminals of the transistors 103 and 104 being tied to a source voltage of the transistors 103 and 104 or to a power supply, the back-gate terminals of the transistors 103 and 104 are coupled to back-gate voltages V_{cal1} and V_{cal2} from the compensation circuit 110.

The differential circuit 101 can be a basic differential circuit block for different applications and circuits, e.g., a circuit block for an amplifier circuit, a mixer circuit, a filter circuit, a current mirror circuit, or a voltage bias circuit. For example, the differential circuit 101 in some of those different applications and circuits can include a differential input signal In₊−In− at a differential input terminal 102 coupled to the gate terminals of transistors 103, 104, and the differential output signal Out₊−Out− at the differential output 105 coupled at the drain terminals of the pair of transistors 103, 104 for an amplifier application. In some implementations, the differential input signal In₊−In− can be coupled to source terminals of the transistors 103, 104. In other implementations, the differential input signal In₊−In− can be coupled to drain terminals of the transistors 103, 104, such as for when PMOS transistors are used in some applications. In some implementations, more than one differential input signal can be coupled to the differential circuit 101, e.g., in a mixer circuit.

In some implementations, NMOS transistor pairs can be used in a differential circuit. In some implementations, PMOS transistor pairs can be used in a differential circuit. In other implementations, circuits with both NMOS and PMOS transistor pairs can be used. Further, the compensation circuit 110 can generate back-gate voltage V_{cal1} at terminal 107 and back-gate voltage V_{cal2} at terminal 108 to adjust the threshold voltages of transistors 103 and 104, respectively.

In some implementations, the calibration control input terminal 106 of the compensation circuit 110 can couple to the differential output 105 as a feedback to the compensation circuit 110. The control circuit 109 may include a narrow, low-pass filter and a comparator to implement a control system that minimizes the direct current (DC) component, also called zeroth-order harmonic, in the differential output signal Out₊−Out− at the differential output terminal 105. The zeroth-order harmonic term usually dominates the even-order harmonic terms in the output signal.

The compensation circuit 110 includes back-gate bias voltage generating circuits 111 and 112 to generate the back-gate voltage V_{cal1} at terminal 107 and back-gate voltage V_{cal2} at terminal 108, in which the back-gate bias voltage generating circuits 111 and 112 may include analog and voltage sweepers and/or a ramping circuit. In some implementations, the control circuit 109 can include a digital signal processor (DSP) to minimize the DC component in the differential output signal Out₊−Out− at the output terminal 105. In some implementations, the control circuit 109 can generate a digital word to control the generation of the back-gate voltages V_{cal1} and V_{cal2} by the back-gate bias voltage generating circuits 111 and 112. Because the DC component may be the dominate even-harmonic term, minimizing the DC component in the differential output signal Out₊−Out− can compensate for circuit mismatches, and may therefore effectively reduce or eliminate all other even harmonics in the differential output signal Out₊−Out−.

In some implementations, an external baseband circuit or DSP can generate the digital control word for the control input signal at the compensation circuit's control input terminal 106. The control circuit 109 may receive the digital control word.

The mismatches in the differential circuit 101, as well as the accumulative even-order harmonics resulting from mismatches along the signal path through the differential circuit 101, can be compensated to reduce or eliminate the even-order harmonics to meet a system requirement. In some implementations, the back-gate bias voltage generating circuits 111 and 112 can be passive networks, e.g., a serial or a parallel resistive network. In other implementations, the back-gate bias voltage generating circuits 111 and 112 can include digital-to-analog converters (DAC), e.g., a binary weighted DAC, an interpolating DAC, or a sigma-delta DAC.

In some implementations, both the back-gate voltages V_{cal1} and V_{cal2} can be varied from another voltage, such as a reference voltage, a source voltage, or a power supply of the pair of transistors 103 and 104. In some implementations, one of the back-gate bias voltages V_{cal1} and V_{cal2} can be a fixed voltage. In some implementations, both back-gate terminals of the pair of transistors 103 and 104 can be biased by a common back-gate voltage. Furthermore, the even-order harmonics calibration process described above can reduce or eliminate even-order harmonics that may arise from accumulative differential circuit mismatches along a signal path through the differential circuit 101 in a differential circuit system.

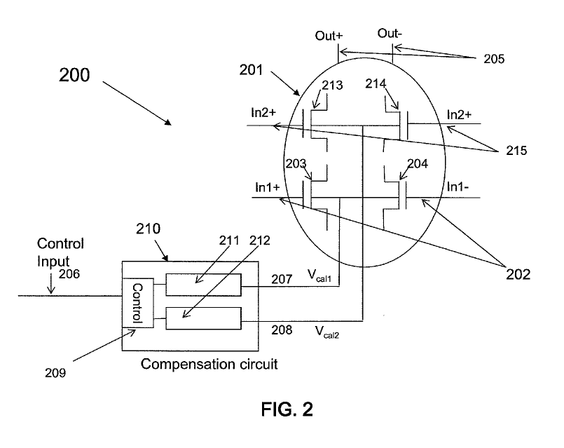

FIG. 2 depicts a schematic of an example of a circuit 200, in which the circuit 200 includes a differential circuit 201 coupled to a compensation circuit 210. The circuit 200 is similar to circuit 100, except the circuit 200 has a different differential circuit topology. The differential circuit 201 includes two pairs of identical or near-identical transistors 203 and 204, and 213 and 214. The compensation circuit 210 includes a control circuit 209, a compensation control input 206, back-gate bias voltage generating circuits 211 and 212 to generate analog output back-gate voltage V_{cal1} at terminal 207 and back-gate voltage V_{cal2} at terminal 208. The control circuit 209 can control the back-gate bias voltage generating circuits 211 and 212. In some implementations, the back-gate bias voltage generating circuits 211 and 212 are identical in design (e.g., size, layout, configuration, implementation, etc.), and in other implementations those circuits 211, 212 are different in design.

In some implementations, the first pair of transistors 203 and 204 can be identical or similar to the second pair of transistors 213 and 214. In other implementations, the first pair of transistors 203 and 204 can be different from the second pair of transistors 213 and 214.

The back-gate voltage V_{cal1} at terminal 207 can tune the threshold voltages of the first pair of transistors 203 and 204 to a first threshold voltage, and the back-gate voltage V_{cal2} at terminal 208 can tune the threshold voltage of the second pair of transistors 213 and 214 to a second threshold voltage. The differential circuit 201 can have two differential input signals, differential signal In1₊−In1− at differential input terminal 202, and differential signal In2₊−In2− at a second differential input terminal 215,

In some implementations, the back-gate voltage V_{cal1} can be used to tune the threshold voltages of one transistor from each pair of transistors. For example, transistors 203 and 213 and the back-gate voltage V_{cal2} can be connected and configured to adjust the threshold voltages of the other transistor from each pair, e.g., transistors 204 and 214, according to system requirements. In other implementations, the compensation circuit 210 can generate four different back-gate voltages to tune four threshold voltages of the two pairs of transistors 203, 204 and 213, 214 to different back-gate voltages. In some implementations, the calibration of circuit 200 can be similar to that of circuit 100 to compensate for circuit mismatches of the differential circuit 201, as well as the accumulative even-order harmonics resulting from mismatches along the signal path before entering the differential circuit 201.

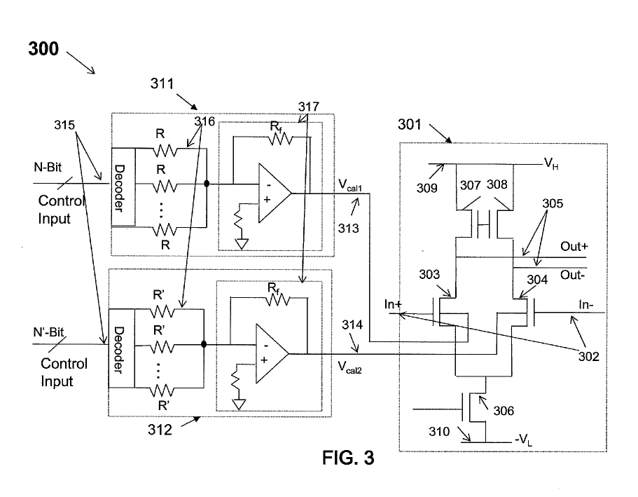

FIG. 3 depicts a schematic of an example of an even-order harmonics calibrated operational amplifier (op amp) circuit 300 that includes an op amp 301 and uses compensation circuit DACs 311 and 312 to generate the back-gate voltages. Op amps are used in many circuits in analog systems or mixed-signal systems. The even-order harmonics calibrated op amp circuit 300 includes a pair of identical (or near-identical) transistors 303 and 304 as an input amplification stage; a differential input terminal 302 coupled to a differential input signal (In₊−In−); a pair of identical (or near-identical) load transistors 307 and 308 as an output stage; a differential output terminal 305 coupled to a differential output signal (Out₊−Out−); a transistor 306 to serve as a current source and coupled to the source terminals of transistors 303 and 304; and compensation circuit DACs 311 and 312 to generate back-gate voltages V_{cal1} and V_{cal2} at the output terminals 313 and 314 of the compensation circuit DACs 311 and 312.

The back-gate voltages V_{cal1} and V_{cal2} can be coupled to the back-gate terminals of the transistors 303 and 304 for adjusting their respective threshold voltages to reduce or eliminate circuit mismatches or asymmetries of the op amp 301 therefore reducing or eliminating the even-order harmonics in the differential output signal 105. Also, accumulated even-order harmonics in the differential input signal at the differential input terminal 302 resulting from previous signal path differential circuit mismatches (not shown in FIG. 3) can also be compensated together with the operational amplifier mismatches by the compensation circuit DACs 311 and 312.

In some implementations, the pair of transistors 303 and 304, as well as the current source transistor 306, can be in NMOS technology, and the pair of transistors 307 and 308 can be in PMOS technology. In some implementations, each of the compensation circuit DACs 311 and 312 can comprise a simple binary-weighted, current-summing, parallel-resistor network 316, and a single-ended op amp 317, which can convert a summed current to a voltage. In some implementations, a DSP circuit (or a baseband circuit) inside or external to the compensation circuit DACs 311 and 312 can use information from the differential output signal Out₊−Out₋ at the differential output terminal 305 to determine an N-bit and an N′-bit digital control, which can also be considered as an (N+N′)-bit digital code, in which N and N′ are positive integers. The N-bit and the N′-bit digital control inputs can be coupled to the input terminals 315 of the compensation circuit DACs 311 and 312, respectively, and applied to a decoder in each DAC 311, 312. The N-bit and N′-bit control inputs can control the generation of the back-gate bias voltages V_{cal1} and V_{cal2}, which are coupled to respective output terminals 313 and 314 of the calibration DACs 311 and 312.

A source voltage of NMOS transistors 303 and 304 of the amplification input stage of the op amp can be V_{ds}−V_{L}, where V_{ds} and −V_{L} represent a drain to source voltage and a supply voltage of transistor 306, respectively. The back-gate voltages V_{cal1} and V_{cal2} at output terminals 313 and 314 can be set to voltages that are different from (V_{ds}−V_{L}). The N-bit control input can also be coupled to the decoder to be decoded to one of 2^{N} digital words as weights to 2^{N} parallel resistors for a fully-decoded compensation circuit DAC 311. Similarly, the N′-bit control input can be decoded by a decoder of compensation circuit DAC 312. In some implementations, N′ may equal to N.

In some implementations, the resistor values in the compensation circuit DACs 311 and 312 can be chosen by determining an upper and a lower bias voltage, and the number of voltage steps desired. For example, the parallel resistors in the compensation circuit DAC 311 can be designed to have the same resistive value R, and the back-gate voltage V_{cal1} can be set between −2^{N}*V_{ref}*R_{f}/R and −V_{ref}*R_{f}/R. In some implementations, the term −2^{N}*V_{ref}*R_{f}/R can be set to V_{ds}−V_{L}, with 2^{N} voltage steps. In some implementations, the parallel resistors of the compensation circuit DAC 311 can have increasing resistance values, R, 2R, 3R, 4R, . . . 2^{N}*R for adjacent resistors, and the back-gate voltage V_{cal1} can be between −(1+2^{N})*2^{(N-1)}*V_{ref}*R_{f}/R and −V_{ref}*R_{f}/R, where −(1+2^{N})*2^{(N-1)}*V_{ref}*R_{f}/R can be set to V_{ds}−V_{L} for 2^{N} voltage steps. Similarly, the compensation circuit DAC 312 can have the same circuit topology as that of DAC 311. Other implementations can have different increasing (or decreasing) resistor values than the above examples. In some implementations, the compensation circuit DACs 311, 312 can have different circuit topologies. In some implementations, only one back-gate bias voltage can be used for both transistors 303 and 304.

An example of an algorithm for utilizing the N-bit and N′-bit digital control input can include varying the N-bit digital control input, and keeping the N′-bit digital control input at a fixed digital word to search for a state of the N-bit control input with a first DC offset in the differential output signal at output terminals 305 that is equal to or below a DC level set by a system requirement. The back-gate voltages corresponding to the first DC offset then can be used for the differential circuit 100.

Another example of an algorithm for utilizing the N-bit and N′-bit digital control input can include varying both the N-bit control input and the N′-bit control input to search for a DC offset in the differential output signal that is equal to or below a DC level set by a system requirement. This algorithm can be used, for example, when the minimum DC offset, which is designated as the first DC offset in the differential output signal and obtained by varying only the N-bit control word, is higher than the DC level set by the system requirement. This algorithm can then vary the N′-bit control word while keeping the N-bit control word corresponding to the first DC offset fixed to search for a DC level in the output signal that is equal to or below the DC level set by a system requirement.

Some implementations of the even harmonics calibration techniques can use a linear search to determine the voltage steps of V_{cal1} and V_{cal2}. Some implementations of can employ a binary search for voltage steps of V_{cal1} and V_{cal2}. Other implementations can use an algorithm for a successive approximation register. Some implementations may involve only generating a single back-gate voltage to be shared for both transistors 303 and 304.

The 2^{N} number of resistors can get very large quickly as N increases, and may make some implementations impractical if N an integer larger 3 or 4. In some implementations, each N-bit digital code can be coupled directly to N parallel resistors in the respective compensation DACs 311 or 312 in the compensation circuit 310, and may form a binary-weighted resistor network. Accordingly, the N-bit digital code in a binary-weighted DAC may need to be a higher number of bits than that of a fully-decoded weighted resistor network to have that same accuracy. For some applications (e.g., Wideband Code Division Multiple Access (WCDMA), Global System for Mobile Communications (GSM), Long Term Evolution (LTE), Global Positioning System (GPS) and Wireless Local Area Network (WLAN) receivers, and/or transmitter and/or transceivers), a range of voltages for the back-gate voltage V_{cal1} or V_{cal2} can be on the order of a few tenths of a volt.

In other implementations, the parallel resistor network in the compensation DACs 311 or 312 can include series resistor networks or ladder networks. In other implementations, impedance networks can be used to implement the compensation DACs 311 and 312. In some implementations, a segmented DAC, which maybe a combination of a binary-weighted and fully-decoded DAC architecture, can be employed.

When more than approximately 10-bit accuracy is needed, a binary-weighted, a fully-decoded, or a segmented resistor or impedance network can have a large die area. Accordingly, an interpolating, a sigma-delta DAC or other types of over-sampling or noise-shaping DAC can be used for the compensation circuit DACs 311 and 312.

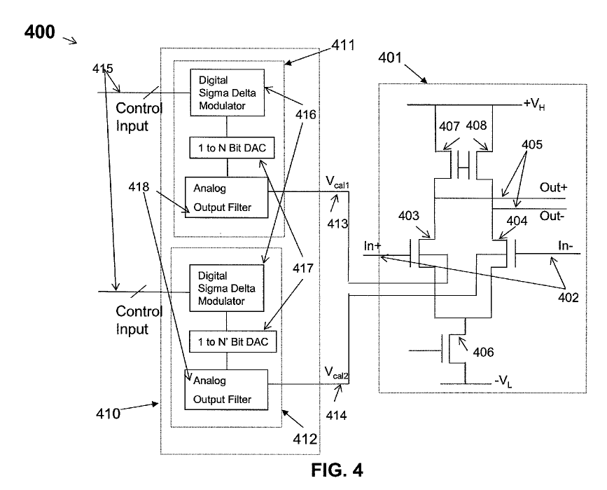

FIG. 4 depicts a schematic of an example of a circuit 400 that employs sigma-delta DACs for back-gate voltage generation. The circuit 400 includes an op amp 401, which is similar to the op amp 301 shown in FIG. 3, and a compensation circuit 410 that includes back-gate bias generating circuits 411 and 412. The op amp 401 can have an input stage having transistors 403 and 404, an output stage having transistors 407 and 408, a differential input terminal 402 and a differential output terminal 405. The op amp 401 is coupled to the back-gate bias generating circuits 411 and 412. The back-gate bias generating circuits 411 and 412 each include a sigma-delta DAC 416 to generate back-gate bias voltages V_{cal1} or V_{cal2} at output terminals 413 or 414 that couple into the op amp 401 at transistors 403 and 404.

Sigma-delta DACs can also be referred to as delta-sigma modulators. Each of the back-gate bias generating circuits 411 and 412 includes a digital sigma-delta modulator 416, a (1 to N)-bit and (1 to N′)-bit DACs 417 and an analog output filter 418. A digital control input signal from an internal or external DSP or a baseband circuit can be received at input terminals 415 by each of the sigma-delta modulators 416 in compensation circuit 410, and the digital control input signal can be converted to a one-bit modulated signal at a modulated frequency.

The one-bit resolution can be increased by using over-sampling or noise-shaping techniques by DACs 417. Over-sampling or noise-shaping techniques can be used in some implementations to reduce a required amount of die area, especially for high DAC resolutions. The one-bit digital output of the digital sigma-delta modulators then can be converted to an analog voltage by the (1 to N)-bit and (1 to N′)-bit DACs 417 before being filtered by the analog output filter 418 to generate the back-gate voltages V_{cal1} and V_{cal2} at output terminals 413 and 414 of the compensation circuit 410, respectively. By employing the even-order harmonics calibration techniques described above, the back-gate voltages V_{cal1} and V_{cal2} can tune voltages at back-gate terminals of transistors 403 and 404 to reduce or eliminate even-order harmonics in a differential output signal Out+−Out− at the output terminals 405 of the op amp 401.

In some implementations, the even-order harmonics compensation circuits 310 in FIG. 3, and 410 in FIG. 4 can receive analog inputs to generate back-gate voltages V_{cal1} and V_{cal2} at their respective output terminals.

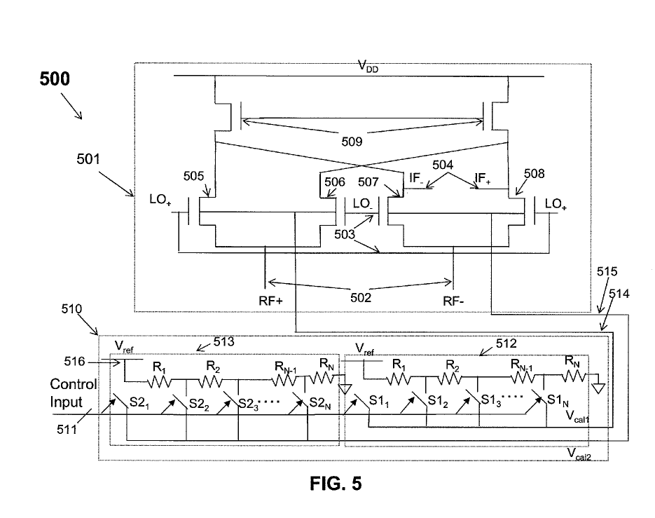

FIG. 5 depicts a schematic of an example of a circuit 500 that includes a differential passive mixer circuit 501 and a compensation circuit 510 that includes back-gate generating circuits 512 and 513, each having a network of resistors and switches.

The mixer 501 includes transistors 505-508 for performing mixing functions, and transistors 509 serving as load transistors. Transistors 505-508 may all be identical or near identical, or each differential pair of transistors (transistor pair 506, 506, and transistor pair 507, 508) can have transistors that are identical or near identical. In some embodiments, the transistors 505-508 can be transmission gate PMOS transistors, and can serve as switches. A differential RF signal RF+−RF− can be coupled at drain terminals 502 of the transistors 505-508 to be mixed with a local oscillator signal LO+−LO− from a local oscillator (not shown) at gate terminals 503 of the transistors 505-508. A mixed, differential intermediate frequency signal IF+−IF− is coupled to source terminals 504 of the transistors 505-508. The voltages at the source terminals of the transistors 505-508 can be V_{ref}-Vload_{ds}, where V_{ref} represents the value of the supply voltage 516 and Vload_{ds} is the drain-to-source voltage of the load transistors 509.

Each of the back-gate bias voltage generating circuits 512 and 513 includes a serial resistor network R₁, R₂ . . . R_{N-1} and a terminal resistor R_{N} to generate back-gate voltages V_{cal1} and V_{cal2} at output terminals 514 and 515, respectively. In some implementations, the back-gate bias voltage generating circuits 512 and 513 can be different from each other. In other implementations, both of the back-gate bias voltage generating circuits 512 and 513 can have the same circuit design. An N-bit control input and an N′-bit control input, which can be the same as an (N+N′)-bit control input, can be received at an input terminal 511 of the compensation circuit 510 from a baseband circuit (not shown) or a DSP (not shown). The (N+N′)-bit control input can control switches S1₁-S1_{N} and S2₁-S2_{N′} to vary the back-gate voltages V_{cal1} and V_{cal2}. The back-gate voltage V_{cal1} can couple to transistors 505 and 506, and the back-gate bias voltage V_{cal2} can couple to transistors 507 and 508.

For an example implementation where N′=N, the back-gate voltages V_{cal1} and V_{cal2} can vary from V_{ref}*(R₁+R₂ . . . +R_{N-1})/((R₁+R₂ . . . +R_{N}) to V_{ref} with N number of steps. For R₁ . . . R_{N-1} having a same resistor value R, the back-gate voltages V_{cal1} and V_{cal2} can vary from V_{ref}*(N−1)*R{1/[(N−1)*R+R_{N})]} to V_{ref}.

For an example implementation of a mixer in a WCDMA receiver with V_{ref}=1.2 volt, N can be equal to 8, and R_{N} can be equal to 2.333*R, and the back-gate voltages V_{cal1} and V_{cal2} can vary form 0.9 volt to 1.2 volts, with voltage steps of 0.0375 volts. The voltage at the source terminals of the transistors 505-508 can be 0.9 volts.

In some implementations, an even-order harmonics calibration process can be performed by sending a single-tone differential RF signal, RF+−RF−, at input terminals 502. One (e.g., V_{cal1}) of the back-gate voltages V_{cal1} and V_{cal2} can be increased from 0.9 volt in steps of 0.0375 volts, while the other (e.g., V_{cal2}) back-gate voltage can be kept at 0.9 volts. A DC level in the differential output signal Out+−Out− can be measured to obtain a DC level that is equal to or below a DC level of a system requirement. If V_{cal1} can meet a system DC level requirement, Vm_{cal1}, in the differential output signal Out+−Out−, the back-gate voltages can be V_{cal1}=Vm_{cal1} and V_{cal2}=0.9 volts for the mixer 501.

In some implementations, generating a DC offset that meets the system requirement may not be achieved by varying only one back-gate voltage. For these implementations, the even-order harmonics calibration process can be carried out by varying both back-gate bias voltages. The calibration process can then be continued by increasing V_{cal2} from 0.9 volts in steps of 0.0375 volts, while keeping V_{cal1}=Vm_{cal1} until the DC offset of the differential output Out+−Out− meets the system requirement at V_{cal2}=Vm_{cal2}. In some implementations, a two-tone input signal may be employed for even-order harmonics calibration that employs the described techniques.

In some implementations, one back-gate voltage can be used for the transistors 505-508, e.g., where V_{cal1}=V_{cal2}. In other implementations, the back-gate voltage V_{cal1} can couple to transistors 505 and 508, and the back-gate bias voltage V_{cal2} can couple to transistors 506 and 507. In some implementations, each back-gate terminal of the transistors 505-508 can be biased by a different back-gate voltage, for a total of four back-gate voltages. In some implementations, the back-gate voltages V_{cal1} and V_{cal2} can decrease from a voltage value of the source voltage, e.g., 0.9 volts by employing V_{ref}=0.9 volts.

In some implementations, the transistors 505-508 can be NMOS transistors. In other implementations, the back-gate bias voltage generating circuits 512 and 513 can include resistor networks, impedance networks, DACs (e.g., a binary-weighted DACs), an interpolating DAC, or a sigma-delta DAC. In some implementations, a passive mixer can be used instead of an active mixer.

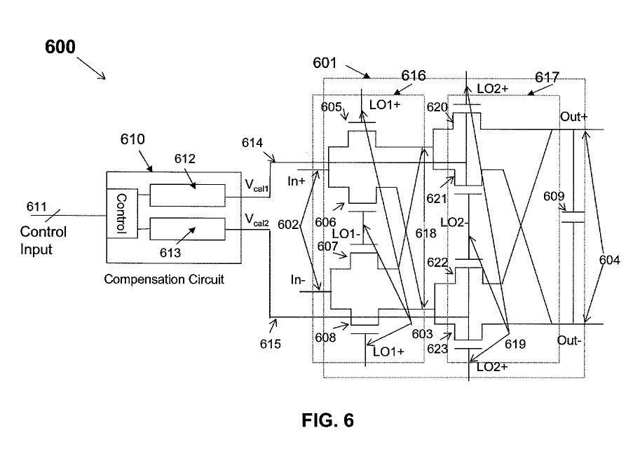

FIG. 6 depicts a schematic of an example of a circuit 600 that includes a two-stage passive mixer circuit 601 and a compensation circuit 610. The circuit 600 may be used in, for example, applications for frequency down conversions. The compensation circuit 610 is similar to the compensation circuit 101 in FIG. 1 for generating back-gate voltages V_{cal1} and V_{cal2} to reduce or eliminate even-order harmonics in a differential output signal Out₊−Out− at output terminals 604 of the passive mixer circuit 601. The two-stage passive mixer circuit 601 can include a first mixer 616 having transistors 605-608, and a second mixer 617 having transistors 620-623. In some implementations, the first and the second mixers 616 and 617 may be similar to the passive mixer 501 shown in FIG. 5 and can include transistors 605-608 and 620-623, respectively. A differential input signal In₊−In− is coupled to the input terminals 602 of the passive mixer circuit 601 to mix with a first differential local oscillator signal LO1₊−LO1₋ at the gate terminals 603 of the transistors 605-608. A differential output signal of the first mixer 616 can couple to input terminals 618 of transistors 620-623 of the second mixer 617 to mix with a second differential local oscillator signal LO2₊−LO₂₋ at gate terminals 619 of the transistors 620-623.

In some implementations, the differential oscillator signals LO1 and LO2 can have different frequencies, duty cycles, and/or different phases. In some implementations, the differential local oscillator signal LO1 can be independent and distinct from the differential local oscillator signal LO2. A differential output signal Out₊−Out₋ can couple to output terminals 604 of the mixer 601, and a load capacitor 609 across the differential output terminals 604 can filter out undesired signals.

The compensation circuit 610 can generate back-gate voltages V_{cal1} and V_{cal2} to tune voltages at the back-gate terminals 614, 615 of respective transistors 620-621 and transistors 622-623 in the second mixer 617 to reduce, eliminate, or minimize even-order harmonics in the differential output signal of the passive mixer circuit 601. In some implementations, the back-gate voltages V_{cal1} and V_{cal2} may also or instead only couple to the back-gate terminals of the respective transistors 605-606 and the transistors 607-608 in the first mixer 616. In other implementations, there can be additional back-gate bias voltages generated by compensation circuit 610 to separately tune the voltages at the back-gate terminals of the transistors 605-608. The even-order harmonics calibration techniques described above can be utilized to reduce or eliminate even-order harmonics in the differential output signal of the passive mixer circuit 601.

In some implementations, the differential input terminals 602 and output terminals 604 of the passive mixer circuit 601 can be configured to operate in a reverse signal path for up-converting a differential input signal received at terminals 604 to a higher frequency differential output signal at terminals 602. The frequencies, duty cycles and the phases of the differential local oscillator signals LO1 and LO2 can vary according to application requirements.

In some implementations, an additional number of mixer stages can be employed to obtain a desired frequency conversion rate. Some implementations of the circuit 600 can be configured to receive a differential in-phase signal and a differential quadrature-phase local oscillator signal. In other implementations, the local oscillator signals can be 50% duty cycles. In some implementations, the local oscillator signals can have duty cycles that are different from 50% duty cycles, e.g., 30% or 25% duty cycles.

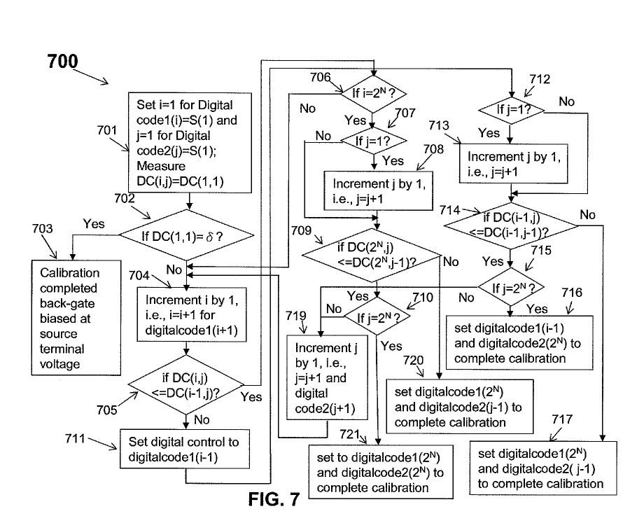

FIG. 7 depicts a flow chart of an example of a process 700 for controlling back-gate voltage generations. In FIG. 7, the process 700 is depicted for generating two N-bit digital control codes for compensation circuits that employ digital control codes. Assuming that N=N′, each N-bit digital control input can be represented by 2^{N} different states: digitalcode1(i), and digitalcode2(j), where i=1,2, . . . 2^{N} and j=1,2 . . . 2^{N} for sequentially increasing or decreasing back-gate voltages. The states digitalcode1(i) and digitalcode2(j) can sequentially increase or decrease the back-gate voltages V_{cal1} and V_{cal2}.

The process 700 can begin by utilizing a single tone differential signal that is sent to the inputs in an operation (at 701), and digitalcode1(1) and digitalcode2(1) are both set at an initial state i=1 and j=1. In some implementations, at the initial state digitalcode1(1) and digitalcode2(1) for i=1 and j=1, the back-gate voltages can be biased at a voltage such as the source terminal voltage or a supply voltage. The process 700 involves a determination (at 702) of measuring the DC level in the differential output Out₊−Out₋, shown for example in FIGS. 3 and 4, to see if it is equal to or less than a small value δ, which may be set according to a system requirement. If this determination (at 702) is true, the two digital controls can be maintained at state digitalcode1(1) and digitalcode2(1) for i,j=1,1, and the process 700 can be completed using the back-gate voltage in an operation (at 703), in which the back-gate voltage may be biased at the source terminal voltage.

If this determination (at 702) is not true, then one of the N-bit digital controls, e.g., digitalcode2(j), can be maintained at j=1 first, and the other N-bit digital control, e.g., digitalcode1(i), can go to a next state (i+1) by incrementing i to i+1 an operation (at 704), where i=1 for the first iteration. The process 700 can involve a determination (at 705) involving comparing the DC(i,j) level corresponding to digitalcode1(i) and digitalcode2(j) in the differential output Out₊−Out₋ with a previous DC(i−1,j) level to see if it decreased or stayed the same. If this determination (at 705) is true, the calibration process can make a determination (at 706) to see if i=2^{N}. If this determination (at 706) is not true, the algorithm can reiterate to an operation (at 704), and increment to the next digitalcode1(i+1). If this determination (at 706) is true, the algorithm can go to on to make a determination (at 707) to check if j=1. If this determination (at 707) is not true, the algorithm can be used to make another determination (at 709) to see if DC(2^{N},j)<=DC(2^{N},j−1). If the determination (at 707) is true, j can be incremented by 1 to j=2 (at 708) and the digital control can be set at digitalcode2(j+1=2) before going to onward to the other determination (at 709).

At this determination (at 709) in the process 700, the DC(2^{N},j) can be compared with a previous DC(2^{N},j−1) to see if it decreases or stays the same. If this determination (at 709) is not true, the process 700 can go to an operation (at 720) to set the digital controls at digitalcode1(2^{N}) and digitalcode2(j−1), which may complete the process 700. If this determination (at 709) is true, the process 700 can conduct a determination (at 710) to see if j=2^{N}. If this determination (at 710) is true, an operation (at 721) is utilized so the digital controls can be set to digitalcode1(2^{N}) and digitalcode2(2^{N}) to complete the calibration. If this determination (at 710) is not true, the process 700 can utilize an operation (at 719) to a next digitalcode2(j+1) by incrementing j by 1 to j+1 before iterating at another operation (at 704).

After incrementing in that operation (at 704), if the next determination (at 705) is not true, the process 700 can have an operation (at 711) to set the digital control back to the previous state digitalcode1(i−1) before going onward to make another determination (at 712). At this point, the process 700 involves a determination (at 712) that can check to determine if j=1. If j=1 in the determination (at 712), j is incremented by 1 to j=j+1=2 in an operation (at 713) before going on to the next determination (at 714). If j is not equal to 1 (at 712), the process 700 can go to the next determination (at 714). The process 700 at this determination (at 714) compares DC(i−1,j) with DC(i−1,j−1) to see if it decreases or stays the same. If this determination (at 714) is not true, the process 700 can go to the next operation (at 717) to set the digital controls to digitalcode1(2^{N}) and digitalcode2(j−1) to complete calibration. If this determination (at 714) is true, the process 700 can go to a determination (at 715) to check if j=2^{N}. If this determination (at 715) is not true, the algorithm can reiterate back to an incrementing operation (at 719). If this determination (at 715) is true, the algorithm can go to an operation (at 716) to set the digital controls to digitalcode1(i−1) and digitalcode2(2^{N}) to complete the calibration.

In some implementations, the calibration controls can generate increasing or decreasing back-gate voltages from the source voltage. In some implementations, the calibration controls can generate both increasing and decreasing back-gate voltages from the source voltage. In some implementations, the DC level comparison can be performed by a DSP inside or external to the compensation circuit or a baseband circuit. In some implementations, the DC level comparison can be achieved by dedicated analog and/or digital circuits. In some implementations, the compensation circuits shown in FIGS. 1-2 and FIG. 6 can be analog circuits with ramping analog voltages. In some implementations, the N-bit digital control can have N states, e.g., digitalcode1(i) and digitalcode2(j), where i=1,2,3 . . . N, and j=1,2,3 . . . N. Some implementations can use a binary search method instead of the above described linear steps. For example, one binary bit can be tested at 1 or 0 and start from the most significant bit (MSB), or start from the least significant bit (LSB) of digitalcode1 or digitalcode2.

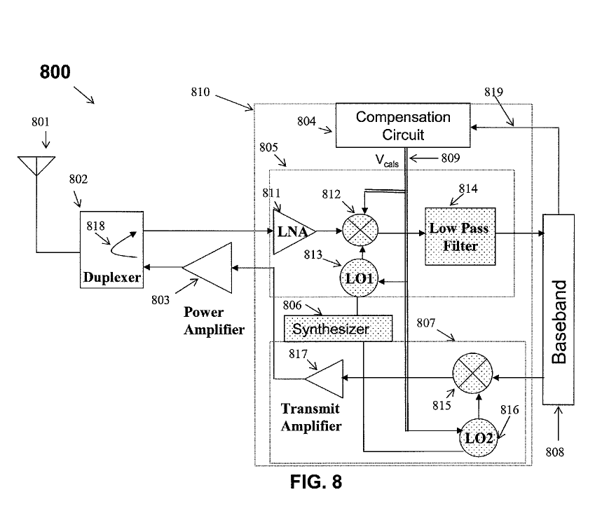

FIG. 8 depicts a schematic of an example of a system 800 with a direct conversion receiver architecture and a compensation circuit 804 employing the even-order harmonics calibration techniques described above. The system 800 includes a transceiver 810, an antenna 801, a duplexer 802, a power amplifier 803, and a baseband circuit 808. The transceiver 810 includes a receiver 805, a transmitter 807, a synthesizer 806, and the compensation circuit 804. The receiver 805 includes a low noise amplifier (LNA) 811, a first differential mixer 812, a first local oscillator (LO1) 813, and a differential low-pass filter 814. The transmitter 807 includes a second mixer 815, a second local oscillator 816, and a transmit amplifier 817.

The system 800 can have a direct down conversion receiver architecture, in which the receiver 805 can also be referred to as a zero intermediate-frequency (IF) receiver. The receiver 805 can employ the first differential mixer 812 to down convert an input radio frequency (RF) signal directly to a baseband frequency. The direct conversion receiver architecture can be used in WCDMA, GSM, LTE, GPS or WLAN receivers, among others.

The system 800 can receive an RF signal via an antenna 801 and a duplexer 802 at an input of the LNA 811 of the receiver 805. The duplexer 802 sends a signal to the LNA 811. An output signal of the LNA 811 can enter the first mixer 812 to mix with a differential output signal of the first local oscillator (LO1) 813, in which the input signal to LO1 813 is generated from a synthesizer 806 having differential circuits. An output signal of the first mixer 812 can then be filtered by a differential low-pass filter 814 before entering the baseband circuit 808 for further processing. The compensation circuit 804 has a digital control input at terminal 819 from the baseband circuit 808 to provide an input control signal to the compensation circuit 804.

For transmission, the baseband circuit 808 can send a transmission signal to the transmitter 807. The transmitter 807 in FIG. 8 includes a second differential mixer 815 to up convert the transmission signal with a differential output signal of the second local oscillator (LO2) 816, in which an input signal for LO2 816 is generated by the synthesizer 806. An output transmission signal of the second mixer 815 can be amplified by a transmit amplifier 817 before entering the power amplifier 803, and sent to the duplexer 802 to be transmitted by the antenna 801.

Even-order harmonics can arise from the mismatches of differential circuits in one or more components of the transceiver 810. Also, transmission signals sent to the duplexer 802 can leak via a path 818 of the duplexer 802. The leak via the path 818 can be modeled as an input noise signal to the receiver 805 that adds second-order harmonics in the output signal of the receiver 805. By employing the techniques described above, the compensation circuit 804 can generate back-gate voltages V_{cals} at terminal 809 to compensate for uneven differential circuit symmetries and reduce or eliminate even-order harmonics in signals.

The compensation circuit 804 can be utilized to calibrate one or more differential components in the transceiver 810, e.g., patterned components blocks shown in FIG. 8, such as the first mixer 812, the low-pass filter 814, the synthesizer 806, the LO1 813 and the LO2 816. The patterns that were not in the patterned component blocks in FIG. 8, (e.g., the second mixer 815, the transmit amplifier 817 and the LNA 811) can also be calibrated by the compensation circuit 804 if required by a system specification.

The even-order harmonics calibration techniques can be employed especially for the receiver 805 to reduce or eliminate even-order harmonics. The even-order harmonics can corrupt signals from differential circuits that have different circuit symmetries (e.g., non-identical matching of pairs of transistors, devices, connections and layouts in differential circuits), and some of other corruption may be attributed to transmission signal leaks to the input of the receiver 805. In addition, the compensation circuit 804 can reduce or eliminate even-order harmonics that arise from accumulative asymmetries in a signal path. Some implementations can employ the calibration techniques for a component that is positioned near an end or an output of a system, e.g., the first mixer 812 or the low-pass filter 814.

In some implementations, the compensation circuit 804 can have a digital control input at terminal 819 from the baseband 808 to generate the back-gate voltages V_{cals} at terminal 809, by the techniques described above, to compensate for the symmetries to the first mixer 812, the low-pass filter 814, the LO1 813, LO2 816, and/or the synthesizer 806. In some implementations, the synthesizer 806 can include an operational amplifier that can be calibrated by the compensation circuit 804. In some implementations, the low-pass filter 814 can include one or more operational amplifiers that can be calibrated by the compensation circuit 804.

In an example implementation, the even-order harmonics can be reduced or eliminated by first reducing or eliminating a static DC level in the output signal of the receiver 805. For example, this can be achieved with a high pass filter in the baseband 808, without sending any input signal to the receiver 805, and then sending a single tone input to the receiver 805 and using the back-gate voltage tuning techniques described above. In some implementations, the even-order harmonics calibration can be performed by using the techniques described above on a leaked transmission signal from a transmission signal initiated by the baseband circuit 808 instead of sending the single tone input signal to the receiver 805.

In some implementations, the positions of switches, resistors, or other components can be exchanged from the disclosed figures with minimal change in circuit functionality. Various topologies for circuit models can also be used, other than what is shown in the figures. The exemplary designs shown are not limited to CMOS process technology, but may also use other process technologies, such as BiCMOS (Bipolar-CMOS) process technology, or Silicon Germanium (SiGe) technology. In some implementations, switches can be implemented as transmission gate switches. In some implementations, the techniques that have been described can be used with radio architectures that support multiple communication standards, such as GSM/EDGE/WEDGE, and emerging standards, such as WiMAX, LTE, and/or UMB. Some of the techniques that have been described can also be used with multi-band radios, GPS, RX Diversity, WLAN, and/or FM/DTV receivers. Some implementations can eliminate surface acoustic wave (SAW) filters in wireless receivers, and some implementations can enhance system linearity.

Generally, some implementations may involve using different back-gate voltages for a pair of transistors in a differential circuit to calibrate even-order harmonics. In addition, the techniques described here can be used with any other analog/RF or digital algorithms used in communication systems. In some implementations, a circuit for processing radio frequency signals may include more than one pair of transistors with back-gate bias voltages tuned to eliminate the effect circuit mismatches in op amps, mixers, filters, oscillators, PLLs, voltage regulators and/or reference voltages.

The system can include other components, in which the circuit can couple with those components. Some of the components may be or include computers, processors, clocks, radios, signal generators, counters, test and measurement equipment, function generators, oscilloscopes, phase-locked loops, frequency synthesizers, phones, wireless communication devices, and components for the production and transmission of data. The number and order of variable gain and filter stages can vary. In addition the number of controllable steps, as well as the steps sizes of each of the stages of gain can also vary. Other implementations can be within the scope of the following claims.

What is claimed is:

1. A circuit comprising:
a first transistor having a first back-gate terminal;
a second transistor having a second back-gate terminal;
an input terminal coupled to the first and second transistors and configured to receive an input signal;
an output terminal coupled to the first and second transistors and configured to provide a differential output signal; and
a compensation circuit configured to supply one or more back-gate voltages to the first back-gate terminal or the second back-gate terminal such that a circuit mismatch is compensated.

2. The circuit of claim 1, wherein the input signal is a differential signal or a single-ended signal.

3. The circuit of claim 1, wherein the compensation circuit is configured to supply a first back-gate voltage to the first back-gate terminal and a second back-gate voltage to the second back-gate terminal such that the circuit mismatch of the circuit is compensated.

4. The circuit of claim 1, wherein the first and second transistors comprise a differential pair of transistors, and wherein the circuit comprises a differential circuit.

5. The circuit of claim 1, further comprising:
a third transistor having a third back-gate terminal;
a fourth transistor having a fourth back-gate terminal, wherein the third transistor is coupled to the first transistor, wherein the fourth transistor is coupled to the second transistor, and
wherein the compensation circuit is configured to supply one or more back-gate voltages to the third back-gate terminal or the fourth back-gate terminal such that the circuit mismatch is compensated.

6. The circuit of claim 5, wherein the output terminal is coupled to the third and the fourth transistors,

7. The circuit of claim 5, wherein the compensation circuit is further configured to supply the third back-gate voltage to the third back-gate terminal and the fourth back-gate voltage to the fourth back-gate terminal such that a circuit mismatch is compensated.

8. The circuit of claim 7, wherein the second back-gate voltage is equal to the first back-gate voltage and the third back-gate voltage is equal to the fourth back-gate voltage.

9. The circuit of claim 7, wherein the third back-gate voltage is equal to the first back-gate voltage and the fourth back-gate voltage is equal to the second back-gate voltage.

10. The circuit of claim 7 further comprising one or more pairs of differential transistors coupled to the first and second transistors, and the third and fourth transistors, wherein back-gate terminals of the one or more pairs of differential transistors are coupled to the one or more back-gate voltages.

11. The circuit of claim 1, wherein at least one of the back-gate voltages is different from any supply voltages of the circuit.

12. The circuit of claim 1, wherein the compensation circuit is configured to vary the one or more back-gate voltages provided to the first back-gate terminal or the second back-gate terminal such that even-order harmonics in the output signal are reduced or eliminated.

13. The circuit of claim 1, wherein the compensation circuit comprises an input terminal configured to receive a control input signal.

14. The circuit of claim 13, wherein the control input signal is a function of the differential output signal.

15. The circuit of claim 1, wherein the compensation circuit further comprises a digital signal processor.

16. The circuit of claim 1, wherein the compensation circuit comprises an analog-to-digital converter (ADC).

17. The circuit of claim 1, wherein the compensation circuit is configured to utilize a control input signal from a baseband circuit or a digital signal processor that is configured to compare a direct current level in the differential output signal with a fixed value or a variable value.

18. The circuit of claim 1, wherein the compensation circuit comprises one or more back-gate bias voltage generating circuits.

19. The circuit of claim 18, wherein the compensation circuit further comprises a decoder for controlling the one or more back-gate bias voltage generating circuits.

20. The circuit of claim 18, wherein the compensation circuit is configured to compare a direct current level in the differential output signal with a fixed or a varying value,

21. The circuit of claim 18, wherein at least one of the back-gate bias voltage generating circuits comprises a digital-to-analog converter (DAC).

22. The circuit of claim 21, wherein the digital-to-analog converter comprises a sigma-delta DAC, or a type of over-sampling or noise-shaping DAC.

23. The circuit of claim 1, wherein the compensation circuit comprises an impedance network.

24. The circuit of claim 1, wherein the compensation circuit comprises an analog voltage ramping circuit or a sweeping circuit.

25. A method of compensating for circuit mismatches in a differential circuit comprising:
biasing a back-gate terminal of a first transistor in a pair of transistors with a first back-gate voltage;
biasing a back-gate terminal of a second transistor in the pair of transistors with a second back-gate voltage; and
tuning the first or the second back-gate voltages to compensate for circuit mismatches in the differential circuit.

26. The method of claim 25, wherein the tuning of the first or second back-gate voltages comprises tuning the first or second back-gate voltages to compensate for the circuit mismatch in order to suppress even-order harmonics in a differential output signal.

27. The method of claim 25, wherein the tuning of the first or second back-gate voltages comprises comparing a direct current level in a differential output signal with a fixed or a varying value.

28. The method of claim 25, wherein the tuning of the first or the second back-gate voltages comprises increasing or decreasing the first or the second back-gate voltages from respective source voltages of the first or second transistors or from a power supply.

29. The method of claim 25, wherein the tuning of the first or the second back-gate voltages comprises tuning the first or the second back-gate voltages using a compensation circuit, the method further comprising forming an input control signal for the compensation circuit using a differential output signal of the differential circuit.

30. The method of claim 29, wherein forming the input control signal comprises generating the input control signal using a digital signal from a baseband processor or a digital signal processor.

31. The method of claim 29 wherein the compensation circuit further comprises back-gate bias voltage generating circuits, the back-gate bias voltage generating circuits comprising digital-to-analog converters (DAC), impedance networks, or analog voltage ramping circuits.

32. The method of claim 29, further comprising decoding the input control signal in the compensation circuit.

33. The method of claim 32, further comprising utilizing an analog-to-digital converter or a digital signal processor in the compensation circuit to determine the back-gate voltages.

34. A circuit comprising:
a differential operational amplifier comprising:
a first transistor having a first back-gate terminal;
a second transistor having a second back-gate terminal;
an input terminal coupled to the first and second transistors and configured to receive an input signal;
an output terminal coupled to the first and second transistors and configured to provide a differential output signal; and
a compensation circuit configured to receive data relating to the differential output signal of the differential operational amplifier and to supply one or more back-gate voltages to the first back-gate terminal or the second back-gate terminal to adjust a threshold voltage of each of the first and second transistors and suppress even-order harmonics in the differential output signal.

35. The circuit of claim 34, wherein the compensation circuit further comprises back-gate bias voltage generating circuits, an analog-to-digital converter, a digital signal processor, or a decoder for controlling the back-gate bias voltage generating circuits.

36. The circuit of claim 35, wherein the back-gate bias voltage generating circuits comprise a resistive network, an impedance network, a digital-to-analog converter (DAC), an analog voltage ramping circuit, or a sweeping circuit.

37. The circuit of claim 34, wherein an input control signal is coupled to the compensation circuit, wherein the input control signal is determined by comparing a direct current level in the differential output signal to a fixed or a variable value.

38. The circuit of claim 37, further comprising a processor to generate the input control signal based on the differential output signal.

39. The circuit of claim 37, wherein the compensation circuit is configured to generate the one or more back-gate voltages from a source voltage of the first or second transistors or from a power supply.

40. The circuit of claim 34, wherein the first transistor and the second transistor comprise a first pair of differential transistors.

41. A circuit comprising:
a differential mixer circuit comprising:
a first transistor having a first back-gate terminal;
a second transistor having a second back-gate terminal;
a first input terminal coupled to the first and second transistors at a stage in the differential mixer circuit and configured to receive a first input signal; and
a second input terminal coupled to the first and second transistors at the same stage in the differential mixer and configured to receive a second input signal, wherein the differential mixer circuit is configured to mix the first and second input signals to generate a differential output signal; and
a compensation circuit configured to receive data relating to the differential output signal of the differential mixer circuit and to supply one or more back-gate voltages to the first back-gate terminal or the second back-gate terminal to adjust a threshold voltage of each of the first and second transistors and suppress even-order harmonics in the differential output signal.

42. The circuit of claim 41, wherein the stage of the differential mixer circuit comprises a first stage of the differential mixer circuit.

43. The circuit of claim 41, wherein the stage of the differential mixer circuit comprises a stage that is after a first stage of the differential mixer circuit.

44. The circuit of claim 41, wherein the differential mixer circuit is a passive differential mixer circuit.

45. The circuit of claim 41, wherein the differential mixer comprises an active differential mixer circuit.

46. The circuit of claim 41, wherein the stage is a first stage of the differential mixer circuit, wherein the differential mixer circuit comprises a second stage, and wherein the second stage comprises:
a third transistor having a third back-gate terminal;
a fourth transistor having a fourth back-gate terminal, wherein the third and fourth transistors couple to the first and second transistors, and wherein the third and fourth back-gate terminals are configured to receive the one or more back-gate voltages; and
a third input terminal coupled to the third and fourth transistors and configured to receive a third input signal to mix with the differential output signal of the first stage of the differential mixer circuit to generate a second differential output signal and to suppress even-order harmonics in the second differential output signal.

47. The circuit of claim 46 wherein the first input signal comprises a radio or audio frequency signal, the second input signal comprises a first local oscillator signal, and the third input signal comprises a second local oscillator signal.

48. The circuit of claim 47 wherein phases of the first and the second local oscillator signals are different, frequencies of the first and the second local oscillator signals are different, or duty cycles of the first and the second local oscillator signals are different.

49. The circuit of claim 41, wherein the first input signal comprises a radio or audio frequency signal and the second input signal comprises a local oscillator signal.

50. A system comprising:
an antenna to receive an input radio frequency (RF) signal;
a duplexer to isolate the input radio frequency signal and an output radio frequency signal, wherein the duplexer is configured to receive the input radio frequency signal from the antenna, receive an output radio frequency signal from a transceiver via a power amplifier, and transmit the input radio frequency signal to the transceiver;
the transceiver comprising:
at least one low noise amplifier to amply the input radio frequency signal and generate an amplified RF signal; and
a synthesizer comprising at least one differential oscillator to utilize the amplified RF signal and generate at least a first differential oscillator signal and at least a second differential oscillator signal, wherein at least one of the differential oscillators comprises:
a first transistor having a first back-gate terminal;
a second transistor having a second back-gate terminal;
an input terminal coupled to the first and second transistors and configured to receive an input signal; and
an output terminal coupled to the first and second transistors and configured to provide a differential output signal for the differential oscillator; and
a compensation circuit configured to receive data relating to the differential output signal of the differential oscillator and to supply one or more back-gate voltages to the first back-gate terminal or the second back-gate terminal to adjust a threshold voltage of each of the first and second transistors and suppress even-order harmonics in the differential output signal of the differential oscillator.
